(19) United States
(12) Patent Application Publication
(10) Pub. No.: US 2021/0309040 A1
(43) Pub. Date: Oct. 7, 2021

(54) LABEL INCLUDING A LENS ARRAY

(71) Applicant: Multi-Color Corporation, Batavia, OH (US)

(72) Inventor: Barron G. McKillip, Batavia, OH (US)

(21) Appl. No.: 17/353,067

(22) Filed: Jun. 21, 2021

Related U.S. Application Data
(63) Continuation of application No. 16/993,833, filed on Aug. 14, 2020.
Application No. 16/993,833 is a division of application No. 16/254,871, filed on Jan. 23, 2019, now abandoned.
(60) Provisional application No. 62/620,691, filed on Jan. 23, 2018.

(51) Int. Cl. B42D 25/36; G02B 3/00; G02B 1/10; B41F 19/00; B42D 25/425; B42D 25/45; B41F 19/02; B42D 25/328; G03F 7/00

(52) U.S. Cl. CPC B42D 25/36; G02B 3/0006; G02B 1/10; B41F 19/001; G03F 7/0002; B42D 25/45; B41F 19/02; B42D 25/328; B42D 25/425

(57) ABSTRACT

A label having a lens array, and methods and system for preparing such a label. The label includes at least one surface, a portion of which is embossed, and a lens array provided by the embossed portion of the at least one surface. The method includes applying a coating to a film, and embossing a portion of the coating to provide a lens array. And the system includes an embossing apparatus associated with a printing apparatus.

### CROSS-REFERENCE TO RELATED APPLICATIONS

The present application is a continuation application of U.S. patent application Ser. No. 16/993,833, filed Aug. 14, 2020 (and published on Nov. 26, 2020 as U.S. Patent Application Publication No. 2020/0369068), the disclosure of which is hereby incorporated by reference in its entirety—which is a divisional application of U.S. patent application Ser. No. 16/254,871, filed Jan. 23, 2019 (and published on Jul. 25, 2019 as U.S. Patent Application Publication No. 2019/0225004), the disclosure of which is hereby incorporated herein by reference in its entirety—which claims priority to, and benefit of the filing date of, U.S. Provisional Patent Application Ser. No. 62/620,691, filed Jan. 23, 2018, the disclosure of which is hereby incorporated herein by reference in its entirety.

### FIELD OF THE INVENTION

The present invention relates to labels incorporating an imprinted lens array, (e.g., Fresnel style lenses) or other optical effects to provide graphically enhanced images in association with the label.

### BACKGROUND OF THE INVENTION

This section is intended to introduce the reader to various aspects of art that may be related to various aspects of the present invention, which are described and/or claimed below. This discussion is believed to be helpful in providing the reader with background information to facilitate a better understanding of various aspects of the present invention. Accordingly, it should be understood that these statements are to be read in this light, and not as admissions of prior art.

Presently, labels can be provided that incorporate an imprinted lens array, such as Fresnel style lenses, which provide visual depth effects not readily achievable with conventional printing methods. However, there are several drawbacks to current versions of those labels.

For example, a current method of incorporating an imprinted lens array on a pressure sensitive label or packaging component is to purchase pre-manufactured substrate films, having images thereon (pre-manufactured embossed films) that are reinserted into a printing press to allow for additional graphics to be added. Another option is called CAST AND CURE™ which is a holographic film available from Breit Technologies of Overland Park, Kans., United States. In the CAST AND CURE™ process, an overprint varnish coating is applied, and then a web of CAST AND CURE™ film, which includes a micro-embossed surface, is laminated over the coating and is cured with UV energy—thereby imparting its micro-embossed pattern onto the coating surface. Alternatively, the images can be applied to a label substrate utilizing cold foil or hot stamp film during the printing process.

However, each of these current methods requires a pre-manufactured film be used, which increases the steps of the process and materials to be used, thereby resulting in an expensive process.

Further, processes requiring that a pre-manufactured film with images thereon be reinserted to a printing press requires proper registration in order to ensure that the additional printed graphics appear properly relative to the pre-printed image. This adds another step to the process where mis-registration can occur, leading to waste of labels, and further increased cost. A label formed from this prior art process is shown in FIG. 1.

Further still, in processes where the images can be applied to a label substrate utilizing cold foil or hot stamp film during the printing process, there are some drawbacks to cold foil printing and hot stamping processes. For examples, hot stamp foils have a release coat on one side and an adhesive layer on the other which can both fluctuate during the manufacturing process of the hot stamp foil. This results in the potential for poor transfer and bond to the label substrate. And, cold foil has a coating on the film that allows the foil to easily release during the printing process. Post printing on the cold foil after application to the label substrate can be difficult due to the release coating present on the surface of the cold foil image. This remains true with the hot stamp image as well. Additionally, both cold foil and hot stamp images easily fail tape testing and product resistance testing.

### SUMMARY OF THE INVENTION

Certain exemplary aspects of the invention are set forth below. It should be understood that these aspects are presented merely to provide the reader with a brief summary of certain forms the invention might take and that these aspects are not intended to limit the scope of the invention. Indeed, the invention may encompass a variety of aspects that may not be explicitly set forth below.

As described above, current methods of incorporating an imprinted lens array on a pressure sensitive label or packaging component are expensive, due to the fact the methods require a separate pre-manufactured film be used. There may also be problems with mis-registration of graphics, due to the necessary re-registration of a preprinted substrate, and problems with methods using cold foil printing and hot foil stamping.

Various aspects of the present invention, however, overcome the drawbacks described in the Background by providing labels, methods of producing same, and apparatus for producing same that eliminate the excessive cost of using pre-manufactured (embossed) films, cold foils, and hot stamp foils. The labels (such as those produced via methods and apparatus described herein) include an imprinted lens array created via embossing a surface on the label in order to provide images thereon. The imprinted lens array associated with the label may be referred to herein as a micro-structure lens array. As used herein, “micro-structure lens array” encompasses forms lens arrays having lenses with dimensions in the nanometer, micrometer, or millimeter ranges. However, it will be recognized by those skilled in the art that the aspects of the invention described herein can be used to provide lens arrays that have dimensions larger or smaller than these ranges.

To those ends, one aspect of the invention provides a label comprising at least one surface, a portion of which is embossed, and a lens array (e.g., a micro-structure lens array) provided by the embossed portion of the at least one surface. In various embodiments, the surface that is embossed may be a surface of a coating, or ink, or varnish, for example.

Another aspect of the invention provides a method for preparing a label. The label may include a lens array (e.g., a micro-structure lens array). In this aspect, the method comprises applying a coating to a film, and embossing a portion of the coating to provide a lens array (e.g., a micro-structure lens array). In alternate embodiments, another surface may have at least a portion thereof embossed.

Another aspect of the invention provides a system for preparing a label having a lens array (e.g., a micro-structure lens array). The system may include an embossing apparatus associated with a printing apparatus.

### BRIEF DESCRIPTION OF THE DRAWINGS

The accompanying drawings, which are incorporated in and constitute a part of this specification, illustrate embodiments of the invention and, together with the general description of the invention given above and the detailed description of the embodiments given below, serve to explain the principles of the present invention.

FIG. 1 is a photograph of a pre-manufacture image substrate that was then re-registered in a secondary process to apply printed graphics (i.e., a prior art process).

FIG. 2 is a schematic of a label in accordance with the principles of the present invention.

FIG. 3 shows an example of an apparatus and process for embossing a surface of a component of a label in accordance with various aspects of the present invention.

FIG. 4 shows an example of an apparatus and process for embossing in accordance with various aspects of the present invention, with the apparatus being shown associated with a printing apparatus.

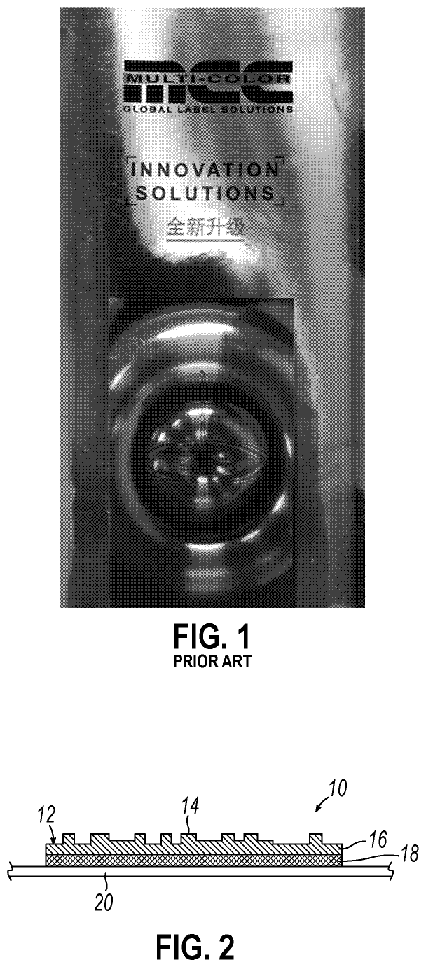

### DETAILED DESCRIPTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As described above, current methods of incorporating an imprinted lens array on a pressure sensitive label or packaging component are expensive, due to the fact the methods require a separate pre-manufactured film be used. There may also be problems with mis-registration of graphics, due to the necessary re-registration of a preprinted substrate, and problems with methods using cold foil printing and hot foil stamping.

Various aspects of the present invention, however, overcome the drawbacks described in the Background by providing labels, methods of producing same, and apparatus for producing same that eliminate the excessive cost of using pre-manufactured (embossed) films, cold foils, and hot stamp foils.

In that regard, and referring now to the Figures, one aspect of the invention provides a label 10 comprising at least one surface 12, at least a portion 14 of which is embossed, such that a lens array (e.g., a micro-structure lens array) is provided by the embossed portion 14 of the at least one surface 12. The label 10 (such as those produced via methods and apparatus described herein) thus includes an imprinted lens array (e.g., a micro-structure lens array) created via embossing a surface 12 on the label 10 in order to provide images thereon (i.e., the lens array provides images associated with the label). As will be described in greater detail below, in embodiments of the invention, a surface of a component of the label (such as a coating 16 on a film 18) may use an embossing process to imprint the lens micro-structure into a surface of the component (e.g., into the surface 12 of the coating 16). By doing so, this embossing process creates the lens array (e.g., micro-structure lens array) that provides images directly in association with a portion of the label (e.g., the coating).

Such images may be provided, in one embodiment, by creating the image on a surface of a portion of the label, as the label is constructed and has other graphics applied. For example, the label 10 may be one of a plurality of labels disposed on a surface of a carrier sheet 20 (a web for labels) as it moves through apparatus for printing graphics on the labels. Thus, the labels 10 on the carrier sheet 20 (web) may each have an embossing process applied thereto to create a lens array (e.g., a micro-structure lens array) providing an image or images. And this can be done in line with additional graphics (designs, logos, text, other indicia, etc.) being printed on the labels.

The processes provided by the various aspects of the present invention that create the lens array (e.g., a micro-structure lens array) of the label may result in the creation of lens elements chosen from the group of Fresnel lenses, lenticular lenses, and microlenses. As is known, a Fresnel lens is a lens having a smaller thickness by concentrically cutting a spherical or aspherical lens having a continuous lens surface (or continuous refracting surface) and structurally has sawtooth prisms disposed stepwise. The sawtooth prisms each include a “lens surface” that turns the direction of light traveling; and a “non-lens surface” that transmits light. The Fresnel lens according to the present invention is a Fresnel lens which has two or more sawtooth prisms and effectively concentrates or disperses light. Further, the lens array (e.g., a micro-structure lens array) can provide a diffraction capability that allows for various optical effects, such as holographic patterns associate with the label.

As described above, in at least one embodiment of the invention, the lens array (e.g., a micro-structure lens array) may be provided in the surface 12 of a coating 16 that is part of the label 10. In various embodiments, this coating may be a clear coating or it, alternatively, may be a colored coating. The structures that make up the lens array may be directly printed onto/into this coating. The coating may be a varnish. One nonlimiting example of a varnish or coating layer that can be used with embodiments of the present invention is SunCure® HG (High Gloss) TL 4098 coating (commercially available under product number RCYFV0484098 from Sun Chemical, of Parsippany-Troy Hills, N.J.). Other nonlimiting examples of a varnish or coating layer that can be used with embodiments of the present invention include BTC 6678 SR, commercially available from Minus Nine of Birdsboro, Pa., and U37860G, commercially available from Nicoat of Itasca, Ill. Each of the above materials is of acrylate chemistry. In various embodiments, the material of the coating may be a UV acrylate.

In one particular embodiment, the surface that is coated is a surface of an overprint varnish of the label. And, in certain embodiments, the varnish has a refractive index in the range of 1.5 to 1.7.

Another aspect of the invention provides a method for preparing a label. The label may include a lens array (e.g., a micro-structure lens array). In this aspect, the method comprises applying a coating to a film, and embossing a portion of the coating to provide a lens array (e.g., a micro-structure lens array).

In one exemplary embodiment, the method for preparing a label in accordance with the principles described herein first includes applying a coating to a film. The coating may be clear or colored, and may be a varnish. The film may be opaque or clear. One nonlimiting example of such a film is a polypropylene film, for example a biaxial oriented polypropylene film, such as that commercially available as TE40 polypropylene film from Amtopp (of the Interplast Group, of Livingston, N.J.). However, it should be recognized that there is no limit to the type of material that can be used as the film. For example, paper, foil, PETG, styrene, polyethylene, polypropylene, acetate, and/or other materials (including anything used in the label and flexible packaging industry) can be used as the film described herein. And, as described above, one nonlimiting example of an imprintable varnish or coating layer is SunCure® HG (High Gloss) TL 4098 coating (commercially available under product number RCYFV0484098 from Sun Chemical, of Parsippany-Troy Hills, N.J.). The application of the coating to the film may be accomplished via a printing process chosen from the group of flexo printing, gravure printing, ink jet printing, or any conventional printing method. In certain embodiments, the coating (e.g., varnish) may be applied to have a thickness of about 50 nm to 150 μm. The coating may be applied as a continuous coating, or it may be applied as a pattern.

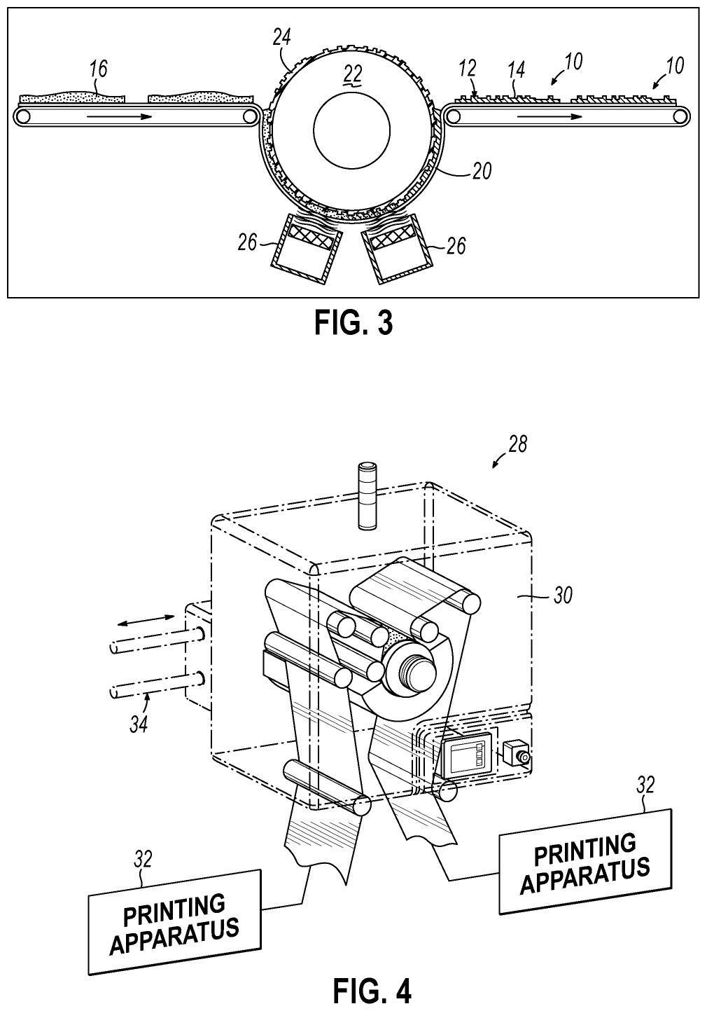

In the method of preparing the label, after applying the coating to the film, a portion of the coating is then embossed to provide the lens array (e.g., a micro-structure lens array). For example, in embodiments of the invention, embossing provides contours in the coating that create, or operate as, a lens array. As the embossed structures can be of size ranging in the nanometers to micrometers, it can be referred to as a micro-structure lens array. (As described above, when “micro-structure lens array” is used herein, that should be taken to encompass not only formed lens structures in the nanometer or micrometer range, but also in the millimeter range.) In one embodiment, an imprint lithography process may be used to provide embossed images in the coating. The scale of the imprinting may range from the extremely small scale (nanometer sized features) to larger (micrometer or even millimeter scale sized features). (Thus, the imprint lithography process may be a nanoimprint lithography process.) To accomplish this, and referring now to FIG. 3, the film having the coating 16 thereon is positioned relative to (e.g., around) a cylinder 22 that has been engraved with an embossing region 24 thereon—such as by being nipped around a cylinder 22 that has been engraved (e.g., via a diamond cut engraving process or a laser engraving process) with an embossing region 24 (which will form the embossed region on at least a portion 14 of the coating 16 of the label 10 to provide the lens array and/or images associated with the label).

The method may then further include curing the coating in order to fix the embossed images thereon or therein. Thus, in one embodiment, the coating 16 may be cured while the coating 16 is in contact with the engraved embossing region 24 on the engraved cylinder 22. In one example of an embodiment, the coating 16 may be cured via a UV-curing process (such as by using a curing apparatus 26, such as a UV powered lamp). In such an embodiment, the base of the cylinder, a UV powered lamp cures the varnish while in contact with the embossed region of the engraved cylinder. Thus, one method of curing is with UV light. Another method is with LED powered UV light. Thus, rather than using a custom designed coating for the creation of the image (a pre-manufactured film), aspects of the present invention use an existing coating (varnish) that is present in the manufacture of the labels. This eliminates extra materials and extra steps of current methods described above, thereby simplifying the process and reducing its cost. Another option is to utilize a clear cylinder in which the UV lamp is positioned in the cylinder and cures through the cylinder where the coating is in contact with the outer surface of the cylinder. This allows one to utilize opaque materials which could not be cured through with the external mounted UV lamp.

The film may then be subsequently printed with remaining graphics in register with the embossed structure. This subsequent printing may be accomplished via any known printing process.

Further, it will be recognized by those of ordinary skill in the art that—while the above embodiment describes first embossing images in the varnish and then printing remaining graphics—this order is not essential. In alternate embodiments, the graphics may be printed first, followed by embossing images.

As described above, another aspect of the present invention provides a system for preparing a label having a lens array (e.g., a micro-structure lens array). Referring to FIG. 4, the system 28 may include an embossing apparatus 30 associated with a printing apparatus 32. Such apparatus may include an embossing station that can be mounted on any printing press. This allows the embossing of images to occur in line with the further printing of additional graphics to a web of labels.

Further, in certain embodiments, the embossing station can be mounted on a rail system 34 which allows it to be moved to any location on the press. Accordingly, the image can be printed at any time during the printing process. Further, because the apparatus (and ability to produce embossed images) is in line on the printing press, the technology can be combined with all forms of labels (e.g., pressure sensitive, heat transfer, shrink sleeve, etc.), packaging, and printed media.

The imaging technology described herein may be combined with any conventional printing processes, including but not limited to UV flexo, rotary screen, lithography, digital, gravure, letterpress, and any combination of conventional printing.

By creating the image during the printing process, labels can be produced that enhance security and offer an anti-counterfeiting benefit. By creating the image in line, the likelihood of theft or duplication of the images is reduced. The potential size of the images that can be produced are in the 100 nm range (or even smaller) making it extremely difficult to detect except with very high magnification. This means that microscopic features may be introduced to the printed image as a “signature” element.

The embodiments of the present invention recited herein are intended to be merely exemplary and those skilled in the art will be able to make numerous variations and modifications to it without departing from the spirit of the present invention. Notwithstanding the above, certain variations and modifications, while producing less than optimal results, may still produce satisfactory results. All such variations and modifications are intended to be within the scope of the present invention as defined by the claims appended hereto.

What is claimed is:

1. A label comprising:
multiple layers, wherein at least one layer includes at least one surface, a portion of which is embossed; and
a lens array provided by the embossed portion of the at least one surface;
wherein the lens array includes a Fresnel lens; and
wherein the surface including the lens array is provided by a coating that is adjacent to a film layer of the label.

2. The label of claim 1, wherein the lens array provides images associated with the label.

3. The label of claim 1, wherein the coating is chosen from the group of a clear coating and a colored coating.

4. The label of claim 1, wherein the coating is provided by a varnish.

5. The label of claim 2, wherein any image associated with the lens array is 100 nm or smaller in at least one dimension of the image.

6. The label of claim 2, further comprising graphics on a portion of the label other than the embossed portion providing the lens array.
